(19) United States
(12) Patent Application Publication
(10) Pub. No.: US 2026/0161198 A1
(43) Pub. Date: Jun. 11, 2026

(54) FLEXIBLE DISPLAY DEVICE

(71) Applicant: LG Display Co., Ltd., Seoul (KR)

(72) Inventor: SungSik SON, Paju-si (KR)

(73) Assignee: LG Display Co., Ltd., Seoul (KR)

(21) Appl. No.: 19/193,735

(22) Filed: Apr. 29, 2025

(30) Foreign Application Priority Data
Dec. 9, 2024 (KR) 10-2024-0181324

(51) Int. Cl. G06F 1/16

(52) U.S. Cl. CPC G06F 1/1652; G06F 1/1656

(57) ABSTRACT

A flexible display device includes a display panel, a link member disposed on a rear surface of the display panel and having a plurality of coupling grooves in one surface thereof, a set cover having a plurality of coupling protrusions respectively inserted into the coupling grooves, and a driving unit connected to at least one of the link member and the set cover to wind or unwind the set cover to ascend or descend. The link member may include a plurality of coupling bars spaced apart in a vertical direction, each having an inclined surface to reduce gaps between adjacent bars, thereby minimizing visual artifacts and enhancing rigidity. The coupling bars may further include a protrusion-and-slit mechanism, wherein a protrusion on one bar is inserted into a slit of an adjacent bar to shield the surface facing the display panel and block foreign matter, thereby improving durability and assembly alignment.

### CROSS-REFERENCE TO RELATED APPLICATION

This application claims the benefit and priority to Korean Patent Application No. 10-2024-0181324, filed in the Republic of Korea on Dec. 9, 2024, which is hereby incorporated by reference for all purposes as if fully set forth herein.

### BACKGROUND

### Technical Field

Embodiments of the disclosure relate to a flexible display device.

### Description of the Related Art

With the recent growth of intelligence society and the development of various portable electronic devices, e.g., mobile communication terminals and laptop computers, display devices, as visual information transfer media, are of more significance.

Recently, flexible display devices which are manufactured of a flexible material, such as plastic, rather than a non-flexible material, e.g., glass substrate, as conventional, to be bendable like paper, but without deterioration of display performance, are rapidly attracting attention as a next-generation display device.

Flexible display devices may adopt a thin film transistor substrate formed of plastic, not glass, and be divided into unbreakable display devices with high durability, bendable display devices that are unbreakable and bendable, rollable display devices, and foldable display devices. These flexible display devices have advantages in space utilization, aesthetics, and design, and may be adopted in various applications, and thus attract attention as next-generation display devices.

The description provided in the background section should not be assumed to be prior art merely because it is mentioned in or associated with the background section. The background section may include information that describes one or more aspects of the subject technology.

### BRIEF SUMMARY

The various embodiments of the present disclosure describe an improved structural design for flexible display devices, specifically targeting the configuration of coupling bars within a link member disposed on a rear surface of the display panel. To reduce visible pattern artifacts and enhance structural rigidity, each coupling bar is formed with an inclined or arc-shaped surface, enabling adjacent bars to be positioned more closely together without interference during bending or rolling. This configuration minimizes the gap between coupling bars while maintaining flexibility, thereby reducing visual distortion on the display and improving mechanical durability.

Additionally, the present disclosure introduces a protrusion-and-slit mechanism between adjacent coupling bars, allowing one bar's protrusion to fit into a corresponding slit in the neighboring bar. This interlocking feature not only shields the surface facing the display panel from moisture and foreign matter but also facilitates accurate alignment and assembly. Collectively, these structural enhancements support a rollable or bendable display that maintains high display quality, mechanical robustness, and environmental resistance.

Embodiments of the disclosure may provide a flexible display device capable of preventing a pattern formed due to a gap between coupling bars from being recognized on the display panel by reducing or minimizing the gap between the coupling bars by forming an inclined surface on an outer surface of the coupling bar.

Embodiments of the disclosure may provide a flexible display device with enhanced rigidity by reducing or minimizing a gap between coupling bars by forming an inclined surface on an outer surface of the coupling bar.

Embodiments of the disclosure may provide a flexible display device with enhanced durability by blocking moisture or foreign substances from flowing into a gap between coupling bars by shielding one surface of the coupling bar.

Embodiments of the disclosure may provide a flexible display device that can be easily wound or unwound by the engagement between the coupling grooves of the link member and the coupling protrusions of the set cover.

Aspects of embodiments of the disclosure are not limited to those set forth herein, and other unmentioned aspects would be apparent to one of ordinary skill in the art from the following description.

To achieve these and other aspects of the inventive concepts, as embodied and broadly described herein, a flexible display device may comprise a display panel, a link member disposed on a rear surface of the display panel and having a plurality of coupling grooves in one surface thereof, a set cover having a plurality of coupling protrusions respectively inserted into the coupling grooves, and a driving unit connected to at least one of the link member and the set cover to wind or unwind the set cover to ascend or descend.

According to another aspect of the present disclosure, there is provided a flexible display device comprising a display panel, a link member disposed on a rear surface of the display panel, and including a support plate and a plurality of coupling bars disposed on one surface of the support plate to be spaced apart in a vertical direction, and having a plurality of coupling grooves formed in one surface thereof, a set cover having a plurality of coupling protrusions respectively inserted into the coupling grooves, and a driving unit connected to at least one of the link member and the set cover to wind or unwind the set cover to ascend or descend.

According to embodiments of the disclosure, there may be provided a flexible display device capable of preventing a pattern formed due to a gap between coupling bars from being recognized on the display panel by reducing or minimizing the gap between the coupling bars by forming an inclined surface on an outer surface of the coupling bar.

According to embodiments of the disclosure, there may be provided a flexible display device with enhanced rigidity by reducing or minimizing a gap between coupling bars by forming an inclined surface on an outer surface of the coupling bar.

According to embodiments of the disclosure, there may be provided a flexible display device with enhanced durability by blocking moisture or foreign substances from flowing into a gap between coupling bars by shielding one surface of the coupling bar.

According to embodiments of the disclosure, there may be provided a low-power display device by using OLEDs as light emitting elements.

The effects of the disclosure are not limited to the foregoing aspects, and other effects will be apparent to one of ordinary skill in the art from the following detailed description.

It is to be understood that both the foregoing general description and the following detailed description are exemplary and explanatory and are intended to provide further explanation of the inventive concepts as claimed.

### DESCRIPTION OF THE SEVERAL VIEWS OF THE DRAWINGS

The accompanying drawings, that may be included to provide a further understanding of the disclosure and may be incorporated in and constitute a part of the disclosure, illustrate embodiments of the disclosure and together with the description serve to explain various principles of the disclosure.

The disclosure will be more fully understood from the following detailed description and the accompanying drawings, which are provided for illustration only and are not intended to limit the disclosure.

FIG. 1 is a side view illustrating a flexible display device according to example embodiments of the disclosure;

FIG. 2 is a side view illustrating an example of driving a flexible display device as illustrated in FIG. 1;

FIG. 3 is a side view illustrating a link member according to an example embodiment of the disclosure;

FIG. 4 is a side view illustrating a state in which a link member and a set cover are coupled according to an example embodiment of the disclosure;

FIG. 5 is a front view illustrating a flexible display device according to an example embodiment of the disclosure;

FIG. 6 is a rear view illustrating a flexible display device according to another example embodiment of the disclosure; and

FIG. 7 is a perspective view illustrating an example of the link member of FIG. 6.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise. Names of the respective elements used in the following explanations may be selected only for convenience of writing the specification and may be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Any implementation described herein as an “example” is not necessarily to be construed as preferred or advantageous over other implementations.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts may be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

To further elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Hereinafter, various example embodiments of the disclosure are described in detail with reference to the accompanying drawings. Further, all the components of each display device according to all embodiments of the present disclosure are operatively coupled and configured. For convenience of description, a scale of each of elements illustrated in the accompanying drawings differs from a real scale, and thus, is not limited to a scale illustrated in the drawings.

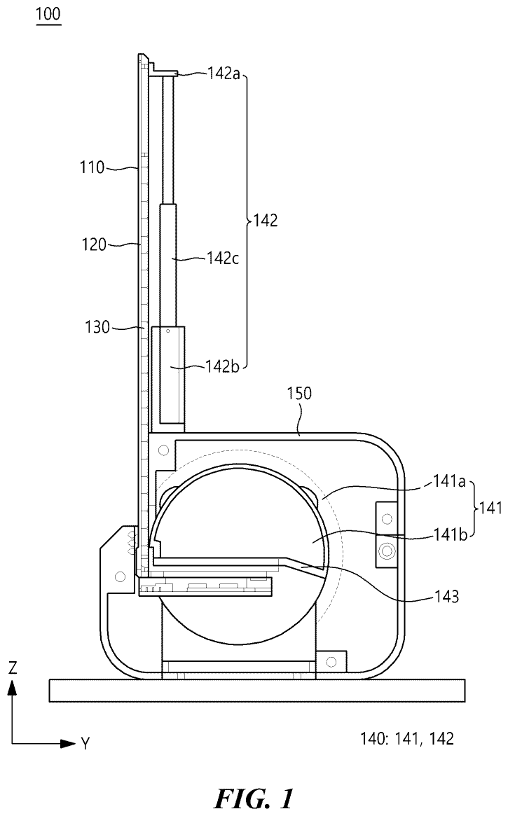

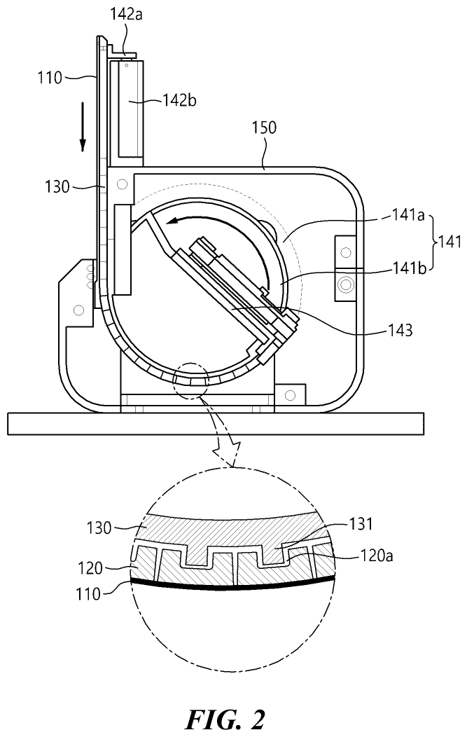

FIG. 1 is a side view illustrating a flexible display device according to example embodiments of the disclosure. FIG. 2 is a side view illustrating an example of driving a flexible display device as illustrated in FIG. 1.

Referring to FIGS. 1 and 2, a flexible display device 100 may include a display panel 110, a link member 120, a set cover 130, and a driving unit 140.

Hereinafter, in embodiments of the disclosure, for convenience of description, it is described that the link member 120 and the set cover 130 are positioned on the rear surface of the display panel 110 under the assumption that the display surface for implementing an image on the display panel 110 faces forward. However, the present disclosure is not limited thereto. For example, if the display surface of the display panel 110 faces rearward, the link member 120 and the set cover 130 may be disposed on the front surface of the display panel 110.

The display panel 110 is a panel in which an image is implemented, and may be repeatedly wound and unwound by the driving unit 140, and an image may be displayed in the unwound state. For example, the lower portion of the display panel 110 may be connected to the driving unit 140 disposed in the housing 150, and the display panel 110 may be formed to be wound or unwound to ascend or descend according to the rotation direction of the driving unit 140.

When the display panel 110 descends, a portion of the display panel 110 may be accommodated in the housing 150, and when the display panel 110 ascends, the portion accommodated in the housing 150 is unfolded to be exposed to the outside of the housing 150, so that an image reproduced from the display panel 110 may be viewed. In this case, an upper portion of the display panel 110 may be exposed to the outside even when entirely wound around the driving unit 140.

On the display panel 110, a light emitting element for implementing an image, a circuit for driving the light emitting element, lines, and components may be disposed. For example, the display panel 110 may include one selected from among a liquid crystal display (LCD) device, a field emission display (FED) device, an electroluminescence display (ELD) device, and an organic light emitting diode (OLED) device. In example embodiments of the disclosure, OLEDs capable of maintaining display performance even when bent like paper, are utilized by way of example only, but the present disclosure is not limited thereto. For example, Inorganic light emitting diode display device formed of micro-LEDs may also be used in the present disclosure.

The OLED is a self-luminous element as a representative element for flexible display devices. Since such OLED does not require a backlight used in a liquid crystal display device, which is a non-light emitting element, it is possible to have a lightweight, thin shape. Further, the OLED has a viewing angle superior to that of the liquid crystal display device, is advantageous in terms of power consumption, is capable of DC low voltage driving, and advantageously has a wide temperature range. In particular, since the manufacturing process is simple, the production costs may be reduced compared to the liquid crystal display device.

The link member 120 supports the rear surface of the display panel 110 and may be fixed to the rear surface of the display panel 110 through a double-sided tape. A plurality of coupling grooves 120a may be formed in one surface of the link member 120, for example, a surface of the link member 120 opposite to another surface thereof facing the display panel 110. For example, the coupling groove 120a may be elongated in the horizontal direction in the rear surface of the link member 120, and there may be a plurality of coupling grooves spaced apart from each other in the vertical direction. Here, the horizontal direction refers to the X-axis direction on the drawings, and the vertical direction refers to the Z-axis direction on the drawings.

The set cover 130 may have a plurality of coupling protrusions 131 inserted into the coupling grooves 120a, respectively. For example, the coupling protrusion 131 may be elongated in the horizontal direction on the front of the set cover 130, and there may be provided a plurality of coupling protrusions spaced apart from each other in the vertical direction. Due to this structure, the link member 120 and the set cover 130 are coupled to each other to move integrally.

The set cover 130 may be formed to be deformable and may be wound and unwound together with the display panel 110. For example, the set cover 130 may be formed of a plastic or metal material capable of elastic deformation and restoration, but the disclosure is not limited thereto.

The driving unit 140 may be connected to at least one of the link member 120 and the set cover 130, and may wind or unwind the display panel 110 to ascend or descend. For example, the driving unit 140 may include a rolling unit 141 and a guide unit 142.

The rolling unit 141 may transfer power of the driving unit 140 to the display panel 110, and may include a motor 141a and a drum 141b.

The motor 141a may be disposed inside or outside the housing 150 and may be formed to rotate clockwise and counterclockwise.

The drum 141b may be connected to a rotation shaft of the motor 141a, and connected to a lower portion of the display panel 110 or the set cover 130. For example, a pair of drums 141b may be formed and may be disposed on one side and the other side, respectively, of the housing 150 and may be connected through a bridge 143. The drum 141b may be formed in a cylindrical shape and may be rotated clockwise or counterclockwise by the motor 141a. Accordingly, when the motor 141a rotates in the counterclockwise direction, the display panel 110 may be wound around the drum 141b, and when the motor 141a rotates in the clockwise direction, the display panel 110 may be unwound from the drum 141b.

The guide unit 142 may move the display panel 110 and the set cover 130 in the vertical direction to change the externally exposed area of the display panel 110 and the set cover 130. One end of the guide unit 142 may be connected to the set cover 130 and the other end may be connected to the housing 150.

The guide unit 142 may include a first bracket 142a, a second bracket 142 b, and a lifting portion 142c.

The first bracket 142a may be coupled to an upper portion of the set cover 130. For example, the first bracket 142a may be disposed on an upper side of the rear surface of the set cover 130, and may be formed in a bar shape elongated in the width direction of the display panel 110 (for example, the horizontal direction or the X-axis direction).

The second bracket 142b may be disposed to be spaced apart from the first bracket 142a downward, and may be coupled to the housing 150. For example, a lower surface of the second bracket 142b may be coupled to an upper portion of the housing 150, and hollows through which the lifting portion 142c is inserted and withdrawn may be formed in two opposite side portions of the second bracket 142b.

One end of the lifting portion 142c may be coupled to the first bracket 142a, and the other end of the lifting portion 142c may be coupled into the hollow of the second bracket 142b to be movable in the vertical direction. For example, the lifting portion 142c may be provided as a piston movable in the vertical direction. Accordingly, when the motor 141a rotates counterclockwise so that the display panel 110 is wound around the drum 141b, the lifting portion 142c may be lowered and inserted into the second bracket 142b, and when the motor 141a rotates clockwise so that the display panel 110 is unwound from the drum 141b, the lifting portion 142c may be raised and withdrawn from the second bracket 142b. For example, the lifting portion 142c may be moved synchronously with the vertical movement of the display panel 110 or the set cover 130.

In other words, when the motor 141a rotates in the counterclockwise direction, the display panel 110 may be wound around the drum 141b, and when the motor 141a rotates in the clockwise direction, the display panel 110 may be unwound from the drum 141b. It is to be noted that, although a specific structure of the driving unit 140 is shown in FIGS. 1-2 by way of example, the present disclosure is not limited thereto, and various other structures of the driving unit 140 may also be similarly adopted when necessary.

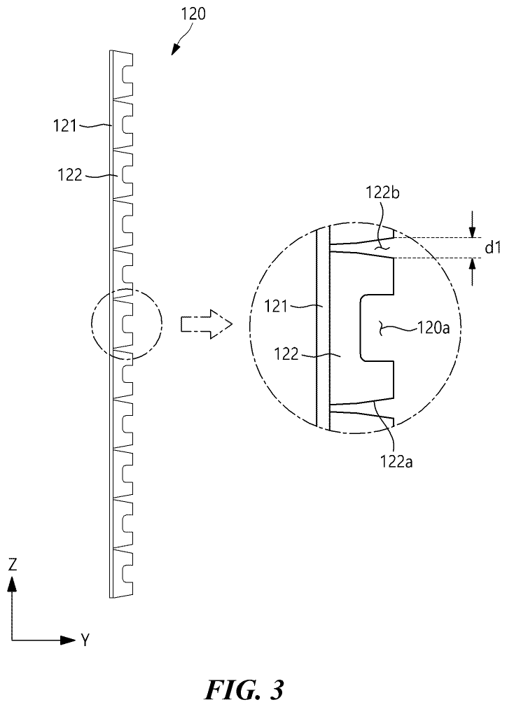

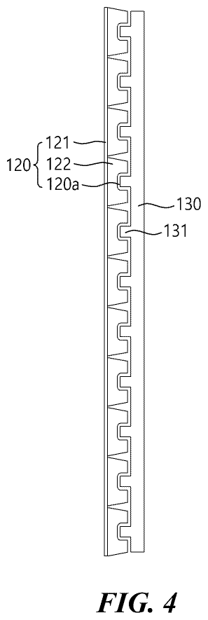

FIG. 3 is a side view illustrating a link member according to an example embodiment of the disclosure. FIG. 4 is a side view illustrating a state in which a link member and a set cover are coupled according to an example embodiment of the disclosure.

Referring to FIGS. 3 to 4, the link member 120 may include a support plate 121 and a coupling bar 122, and may be bent with a predetermined curvature.

The support plate 121 is an element or component where the plurality of coupling bars 122 are fixed, and is formed to be deformable so as to be wound and unwound with the set cover 130. For example, the support plate 121 may be a double-sided tape for coupling the display panel and the link member 120. Further, the support plate 121 may be formed of a plastic or metal material capable of elastically deforming and restoring, but the disclosure is not limited thereto.

The number of the coupling bars 122 may be equal to, or correspond to the number of coupling protrusions 131 formed on the set cover 130, and the coupling bar may be formed in a rectangular bar shape elongated in the X-axis direction. For example, the coupling bar 122 may have a coupling groove 120a formed in the surface facing the coupling protrusion 131. Accordingly, the coupling groove 120a and the coupling protrusion 131 are engaged like sawtooth wheels, so that the link member 120 and the set cover 130 may move together in the circumferential direction.

The inner corner portion of the coupling bar 122 having the coupling groove 120a may be formed in a rounded shape. Accordingly, when the coupling protrusion 131 is engaged to the coupling groove 120a and moves in the circumferential direction, the corner portion of the coupling protrusion 131 may be prevented or reduced from interfering with the coupling bar 122, more flexibly driving the link member 120 and the set cover 130.

The coupling bar 122 may be elongated in the horizontal direction, and there may be provided a plurality of coupling bars 122 disposed on one surface of the support plate 121 to be spaced apart in the vertical direction. Accordingly, a gap 122b may be formed between the adjacent coupling bars 122, and when the link member 120 is wound around the drum 141b, the coupling bars 122 may be deformed between the gaps 122b. In other words, in order to prevent or reduce the end portions of the coupling bars 122 from interfering with each other when the coupling bar 122 is wound around the drum 141b, the gap 122b may be formed to have a predetermined size between the coupling bars 122.

On the other hand, as the gap 122b between the coupling bars 122 increases, the rigidity of the link member 120 may decrease, and the support force to support the set cover 130 may decrease, causing the pattern formed due to the gap 122b to be recognized on the display panel 110. Therefore, it is important to reduce or minimize the gap 122b between the coupling bars 122 while avoiding the interference between adjacent coupling bars 122 when wound around the drum 141b.

In the disclosure, in order to reduce or minimize the gap 122b between the coupling bars 122, the coupling bar 122 may be formed to have an inclined surface 122a where the width of outer surfaces adjacent to each other gradually decreases toward the position of the set cover 130. For example, the inclined surface 122a may be formed to have an inclination of 5° to 15°, specifically, to have an inclination of 7.5° to 12.5°, and more specifically, to have an inclination of 10°. As such, as the inclined surface 122a of the coupling bar 122 is formed, the spacing length (for example, spacing distance or spacing interval) d1 between the coupling bars 122 may gradually increase toward the position of the set cover 130. Therefore, when the link member 120 is bent at the same curvature, the interference between the end portions of the coupling bars 122 which have the inclined surface 122a may be delayed as compared with coupling bars without the inclined surface 122a, so that the gap 122b between the coupling bars 122 may be reduced by the increased spacing length d1.

The inclined surface 122a may be formed in an arc shape convex outwards. When the inclined surface 122a is formed in an arc shape, the spacing length d1 between the end portions of the coupling bars 122 may be increased, and thus the gap 122b between the coupling bars 122 may be reduced or minimized. Therefore, the rigidity of the link member 120 may be enhanced, and at the same time, the pattern formed due to the gap 122b between the coupling bars 122 may be prevented from being visually recognized on the display panel 110.

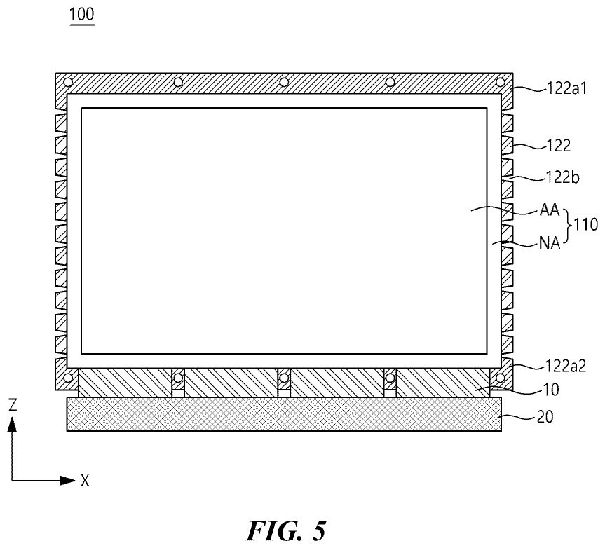

FIG. 5 is a front view illustrating a flexible display device according to an example embodiment of the disclosure.

Referring to FIG. 5, a display panel 110 may include a display area AA in which an image is displayed and a non-display area NA in which an image is not displayed. The non-display area NA may be an area outside of the display area AA or an area adjacent to the display area AA and may also be referred to as a bezel area.

One side of the display panel 110 may be connected to the printed circuit board 20 through the flexible film 10.

The flexible film 10 may be electrically connected to the display panel 110 to supply signals to a plurality of sub-pixels and circuits disposed in the display area AA. For example, the flexible film 10 may be disposed on one side of the non-display area NA, and may be formed of a flexible material to be wound around or unwound from the drum 141b. The number of flexible films 10 is not limited to the example, and may be variously changed according to the design.

The flexible film 10 may include data for displaying an image and a driving IC for processing the data. For example, the driving IC may be disposed in a scheme such as chip on glass (COG), chip on film (COF), tape carrier package (TCP), or the like according to its mounting method.

The printed circuit board 20 supplies a signal to the driving IC, and may be disposed at one end of the flexible film 10 and connected to the flexible film 10. For example, the printed circuit board 20 may supply various signals such as driving signals, data signals, and the like to the driving IC. In the present embodiment, it is illustrated that there is only one printed circuit board 20, but the present embodiment is not limited thereto, and may be variously changed according to the design.

The link member 120 may include a first support member 122a1 disposed above the coupling bars 122 and a second support member 122a2 disposed below the coupling bars 122. For example, the first support member 122a1 and the second support member 122a2, together with the coupling bars 122, may be fixed to the support plate 121.

The first support member 122a1 may be disposed on an upper portion of the rear surface of the display panel 110 to support and protect an upper portion of the display panel 110. For example, the first support member 122a1 may be connected to the first bracket 142 a and may be exposed to the outside even when the display panel 110 is fully wound.

The second support member 122a2 may be disposed under the rear surface of the display panel 110 to support and protect the lower portion of the display panel 110. For example, the second support member 122a2 may be spaced apart from the first support member 122a1 in a downward direction and connected to the drum 141b, and may not be exposed to the outside as it is positioned in the housing 150 even when the display panels 110 are fully unwound.

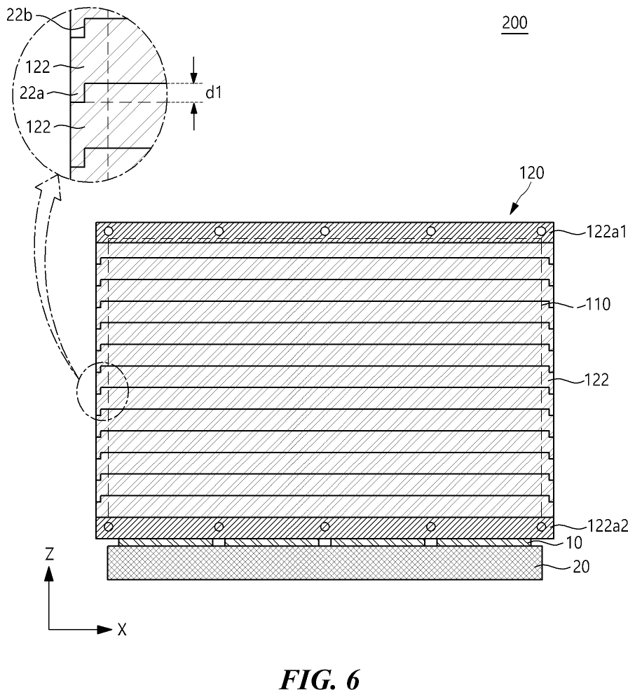

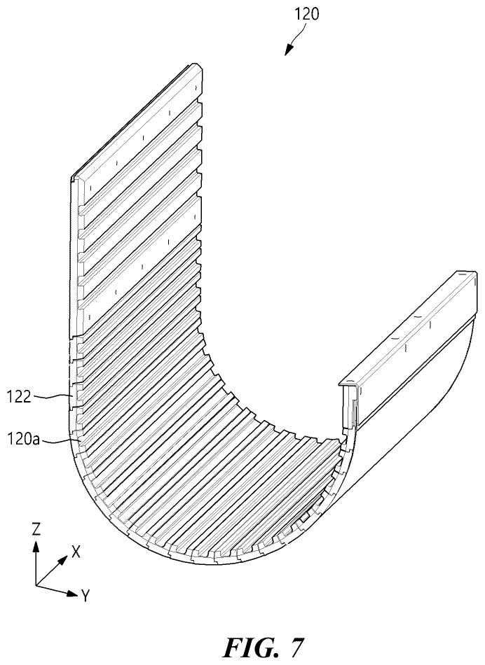

FIG. 6 is a rear view illustrating a flexible display device according to another example embodiment of the disclosure, and FIG. 7 is a perspective view illustrating the link member of FIG. 6. In this embodiment, the description focuses primarily on differences from the above-described embodiment.

Referring to FIGS. 6 to 7, the surface of the coupling bar 122 of the flexible display device 200 facing the display panel 110 may be shielded to enhance moisture permeability resistance. For example, the coupling bar 122 includes a protrusion 22a protruding toward the adjacent coupling bar 122 and a slit 22b formed on the side opposite to the protrusion 22a, and the protrusion 22a provided in one coupling bar 122 may be inserted into the slit 22b provided in the adjacent coupling bar 122 to shield the surface facing the display panel 110. Specifically, the protrusion 22a may protrude in the Z-axis direction, and the length of the protrusion 22a may be equal to or larger than the length d1 of the space between the adjacent coupling bars 122.

As the surface facing the display panel 110 is shielded by the protrusion 22a and the slit 22b, the inflow of moisture or foreign substances into the gap 122b between the coupling bars 122 may be reduced, enhancing the durability of the flexible display device. Further, the assembly position of the coupling bar 122 may be guided through the protrusion 22a and the slit 22b, which may enhance assembly efficiency.

A display device according to an embodiment of the disclosure may be described as follows.

According to embodiments of the disclosure, there may be provided a flexible display device comprising a display panel, a link member disposed on a rear surface of the display panel and having a plurality of coupling grooves in one surface thereof, a set cover having a plurality of coupling protrusions respectively inserted into the coupling grooves, and a driving unit connected to at least one of the link member and the set cover to wind or unwind the set cover to ascend or descend.

According to embodiments of the disclosure, the link member may include a support plate and a plurality of coupling bars elongated in a horizontal direction, disposed on one surface of the support plate to be spaced apart in a vertical direction, and having the coupling grooves in a surface facing the coupling protrusions.

According to embodiments of the disclosure, the coupling bars may be formed to have an inclined surface where a width of outer surfaces adjacent to each other gradually decreases toward a position of the set cover.

According to embodiments of the disclosure, the inclined surface may be formed to have an arc shape convex in an outward direction.

According to embodiments of the disclosure, the inclined surface may have an inclination of 5 degrees to 15 degrees.

According to embodiments of the disclosure, the coupling bar may include a protrusion protruding toward an adjacent coupling bar and a slit formed in a side opposite to the protrusion. The protrusion provided on one coupling bar may be inserted into the slit provided in the adjacent coupling bar.

According to embodiments of the disclosure, a length of the protrusion may be equal to or larger than a length of a space between the coupling bars.

According to embodiments of the disclosure, a surface of the coupling bar, facing the display panel, may be shielded.

According to embodiments of the disclosure, an inner corner portion of the coupling bar having the coupling groove may be formed in a rounded shape.

According to embodiments of the disclosure, the link member may be fixed to the rear surface of the display panel through a double-sided tape.

According to embodiments of the disclosure, the display panel may be a flexible display panel that are wound or unwound together with the set cover.

According to embodiments of the disclosure, there may be provided a flexible display device comprising a display panel, a link member disposed on a rear surface of the display panel, and including a support plate and a plurality of coupling bars disposed on one surface of the support plate to be spaced apart in a vertical direction, and having a plurality of coupling grooves formed in the plurality of coupling bars respectively, a set cover having a plurality of coupling protrusions respectively engaged with the coupling grooves, and a driving unit connected to at least one of the link member and the set cover to wind or unwind the set cover to ascend or descend.

According to embodiments of the disclosure, the coupling bars may be formed to have an inclined surface where a distance between two coupling bars adjacent to each other gradually increases toward a position of the set cover.

According to embodiments of the disclosure, the inclined surface may be formed to have an arc shape convex in an outward direction.

According to embodiments of the disclosure, a surface of the coupling bar, facing the display panel, may be shielded.

According to embodiments of the disclosure, the coupling bar may include a protrusion protruding toward an adjacent coupling bar and a slit formed in a side opposite to the protrusion. The protrusion provided on one coupling bar may be inserted into the slit provided in the adjacent coupling bar.

According to embodiments of the disclosure, a length of the protrusion may be equal to or larger than a length of a space between the coupling bars.

According to embodiments of the disclosure, an inner corner portion of the coupling bar having the coupling groove may be formed in a rounded shape.

According to embodiments of the disclosure, there may be provided a flexible display device comprising a display panel, a link member disposed on a rear surface of the display panel, and including a plurality of coupling bars extending in a first direction and spaced apart from each other in a second direction different from the first direction; and a set cover coupled to the link member, wherein each of the plurality of coupling bars has an inclined surface, such that a distance between two adjacent coupling bars gradually increases toward a position of the set cover.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. In other words, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A flexible display device, comprising:
a display panel;
a link member on a rear surface of the display panel and having a plurality of coupling grooves in one surface thereof;
a set cover having a plurality of coupling protrusions respectively inserted into the coupling grooves; and
a driving unit connected to at least one of the link member and the set cover to wind or unwind the set cover to ascend or descend.

2. The flexible display device of claim 1, wherein the link member includes:
a support plate; and
a plurality of coupling bars elongated in a horizontal direction, on one surface of the support plate to be spaced apart in a vertical direction, and having the coupling grooves in a surface facing the coupling protrusions.

3. The flexible display device of claim 2, wherein the coupling bars have an inclined surface where a width of outer surfaces adjacent to each other gradually decreases toward a position of the set cover.

4. The flexible display device of claim 3, wherein the inclined surface have an arc shape convex in an outward direction.

5. The flexible display device of claim 3, wherein the inclined surface has an inclination of 5 degrees to 15 degrees.

6. The flexible display device of claim 2, wherein the coupling bar includes a protrusion protruding toward an adjacent coupling bar and a slit formed in a side opposite to the protrusion, and
wherein the protrusion provided on one coupling bar is inserted into the slit provided in the adjacent coupling bar.

7. The flexible display device of claim 6, wherein a length of the protrusion is equal to or larger than a length of a space between the coupling bars.

8. The flexible display device of claim 1, wherein a surface of the coupling bar, facing the display panel, is shielded.

9. The flexible display device of claim 1, wherein an inner corner portion of the coupling bar having the coupling groove is formed in a rounded shape.

10. The flexible display device of claim 1, wherein the link member is fixed to the rear surface of the display panel through a double-sided tape.

11. The flexible display device of claim 1, wherein the display panel is a flexible display panel that are wound or unwound together with the set cover.

12. A flexible display device, comprising:
a display panel;
a link member on a rear surface of the display panel, and including a support plate and a plurality of coupling bars disposed on one surface of the support plate to be spaced apart in a vertical direction, and having a plurality of coupling grooves formed in the plurality of coupling bars respectively;
a set cover having a plurality of coupling protrusions respectively engaged with the coupling grooves; and
a driving unit connected to at least one of the link member and the set cover to wind or unwind the set cover to ascend or descend.

13. The flexible display device of claim 12, wherein the coupling bars have an inclined surface where a distance between two coupling bars adjacent to each other gradually increases toward a position of the set cover.

14. The flexible display device of claim 13, wherein the inclined surface have an arc shape convex in an outward direction.

15. The flexible display device of claim 12, wherein a surface of the coupling bar, facing the display panel, is shielded.

16. The flexible display device of claim 12, wherein the coupling bar includes a protrusion protruding toward an adjacent coupling bar and a slit formed in a side opposite to the protrusion, and
wherein the protrusion provided on one coupling bar is inserted into the slit provided in the adjacent coupling bar.

17. The flexible display device of claim 16, wherein a length of the protrusion is equal to or larger than a length of a space between the coupling bars.

18. The flexible display device of claim 12, wherein an inner corner portion of the coupling bar having the coupling groove is formed in a rounded shape.

19. A flexible display device, comprising:
a display panel;
a link member on a rear surface of the display panel, and including a plurality of coupling bars extending in a first direction and spaced apart from each other in a second direction different from the first direction; and
a set cover coupled to the link member,
wherein each of the plurality of coupling bars has an inclined surface, such that a distance between two adjacent coupling bars gradually increases toward a position of the set cover.

20. The flexible display device of claim 19, wherein the inclined surface has an arc shape convex in an outward direction.
